(19) United States
(12) Patent Application Publication
(10) Pub. No.: US 2024/0213062 A1
(43) Pub. Date: Jun. 27, 2024

(54) LED-CHIP SORTING DEVICE AND LED CHIP MANUFACTURING METHOD

(71) Applicant: SAMSUNG ELECTRONICS CO., LTD., Suwon-si (KR)

(72) Inventors: Jongha Hwang, Suwon-si (KR); Yusung Jang, Suwon-si (KR)

(73) Assignee: SAMSUNG ELECTRONICS CO., LTD., Suwon-si (KR)

(21) Appl. No.: 18/534,223

(22) Filed: Dec. 8, 2023

(30) Foreign Application Priority Data
Dec. 21, 2022 (KR) 10-2022-0181071

(51) Int. Cl. H01L 21/67; H01L 33/50

(52) U.S. Cl. CPC H01L 21/67271; H01L 33/50; H01L 2933/0041

(57) ABSTRACT

A light-emitting diode (LED)-chip sorting device includes a wafer stage configured to load a wafer including a plurality of LED chips thereon, a film stage configured to load a film thereon, a pick-up unit configured to arrange, on the film loaded on the film stage, the plurality of LED chips loaded on the wafer stage, and a controller configured to control the pick-up unit to sequentially pick up the plurality of LED chips from the wafer stage in a preset pick-up direction. The preset pick-up direction is one of a first pick-up direction defined from a center portion of the wafer toward an edge of the wafer, and a second pick-up direction defined from the edge of the wafer toward the center portion of the wafer.

### CROSS-REFERENCE TO RELATED APPLICATION

This application is based on and claims priority under 35 U.S.C. § 119 to Korean Patent Application No. 10-2022-0181071, filed on Dec. 21, 2022, in the Korean Intellectual Property Office, the disclosure of which is incorporated by reference herein in its entirety.

### BACKGROUND

Embodiments of the disclosure relate to a sorting device for sorting a light-emitting diode (LED) chip and an LED chip manufacturing method. More particularly, Embodiments of the disclosure relate to an LED-chip sorting device and an LED chip manufacturing method for sorting and transferring LED chips picked up from a wafer stage.

LEDs convert electricity into light using a semiconductor, and may also be called luminescent diodes. LEDs have smaller sizes, longer lifespans, consume less power, and have quicker response characteristics than conventional light sources. Thus, LEDs widely used in various applications such as display devices of automotive gauges, light sources for optical communication, display lamps of electronic apparatuses, number display devices, card readers of payment machines, backlights, or lighting apparatus.

LEDs may be manufactured in the form of small chips through semiconductor manufacturing processes. Processes of manufacturing LED chips may include an epitaxial (EPI) process, a chip (fabrication) process, a package process, an inspection process, a sorting process, and the like.

### SUMMARY

Embodiments of the disclosure provide a light-emitting diode (LED)-chip sorting device capable of selecting a pick-up direction when picking up LED chips from a wafer.

Embodiments of the disclosure provide an LED-chip sorting device and an LED chip manufacturing method for picking up LED chips from a wafer by selecting the pick-up direction of the LED chips.

According to an aspect of the disclosure, there is provided a chip sorting device including: a wafer stage configured to load a wafer including a plurality of light emitting diode (LED) chips on the wafer stage: a film stage configured to load a film on the film stage: a pick-up unit configured to place, on the film loaded on the film stage, one or more of the plurality of LED chips loaded on the wafer stage; and a controller configured to control the pick-up unit to sequentially pick up the plurality of LED chips from the wafer stage in a first direction from a center portion of the wafer towards an edge portion of the wafer or a second direction from the edge portion of the wafer towards the center portion of the wafer.

According to another aspect of the disclosure, there is provided a chip sorting device including: a wafer stage configured to load a wafer including a plurality of light emitting diode (LED) chips on the wafer stage: a film stage configured to load a film on the film stage; a pick-up unit configured to place, on the film loaded on the film stage, one or more of the plurality of LED chips loaded on the wafer stage; and a controller configured to select a pick-up direction in which the plurality of LED chips are picked up from the wafer stage and an arrangement direction in which the plurality of LED chips are placed on the film based on an interacting relationship between the pick-up direction and the arrangement direction.

According to another aspect of the disclosure, there is provided a method of manufacturing a light-emitting diode (LED) chip, the method including: arranging a plurality of LED chips on a wavelength conversion film: curing the wavelength conversion film; and cutting the wavelength conversion film on which the plurality of LED chips are arranged, wherein the arranging of the plurality of LED chips on the wavelength conversion film includes: picking up, by a pick-up unit, the plurality of LED chips from a wafer including the plurality of LED chips and loaded on a wafer stage: and arranging, by the pick-up unit, the plurality of LED chips on the wavelength conversion film provided on a film stage, and wherein the picking up of the plurality of LED chips includes selecting a pick-up direction in which the plurality of LED chips are picked up.

### BRIEF DESCRIPTION OF DRAWINGS

Embodiments will be more clearly understood from the following detailed description taken in conjunction with the accompanying drawings in which:

FIG. 1A is a perspective view illustrating a light-emitting diode (LED)-chip sorting device according to an embodiment:

FIG. 1B is a block diagram illustrating the LED-chip sorting device according to an embodiment;

FIG. 2 is a view illustrating a method of picking up and arranging LED chips using the LED-chip sorting device according to an embodiment;

FIG. 3 is a view illustrating pick-up directions of an LED-chip sorting device according to a comparative example:

FIGS. 4A and 4B are views illustrating a pick-up direction of the LED-chip sorting device according to an embodiment:

FIGS. 5A and 5B are views illustrating a pick-up direction of the LED-chip sorting device according to an embodiment:

FIG. 6 is a table for comparison between effects by the LED-chip sorting device of the embodiments and effects by the LED-chip sorting device of the comparative example:

FIG. 7 is a view illustrating a method of arranging LED chips using the LED-chip sorting device according to an embodiment:

FIG. 8 is a flowchart illustrating an LED chip manufacturing method according to an embodiment: and

FIG. 9 is a flowchart specifically illustrating an operation of arranging LED chips on a wavelength conversion film in the LED chip manufacturing method, according to an embodiment.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The following structural or functional descriptions of examples disclosed in the disclosure are merely intended for the purpose of describing the examples and the examples may be implemented in various forms. The examples are not meant to be limited, but it is intended that various modifications, equivalents, and alternatives are also covered within the scope of the claims.

Although terms of “first” or “second” are used to explain various components, the components are not limited to the terms. These terms should be used only to distinguish one component from another component. For example, a “first” component may be referred to as a “second” component, or similarly, and the “second” component may be referred to as the “first” component within the scope of the right according to the concept of the disclosure.

It will be understood that when a component is referred to as being “connected to” another component, the component can be directly connected or coupled to the other component or intervening components may be present.

As used herein, the singular forms “a”, “an”, and “the” are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof. As used herein, expressions such as “at least one of” when preceding a list of elements, modify the entire list of elements and do not modify the individual elements of the list. For example, the expression, “at least one of a, b, and c” should be understood as including only a, only b, only c, both a and b, both a and c, both b and c, or all of a, b, and c.

Unless otherwise defined, all terms including technical or scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, examples will be described in detail with reference to the accompanying drawings. Regarding the reference numerals assigned to the elements in the drawings, it should be noted that the same elements will be designated by the same reference numerals, and redundant descriptions thereof will be omitted.

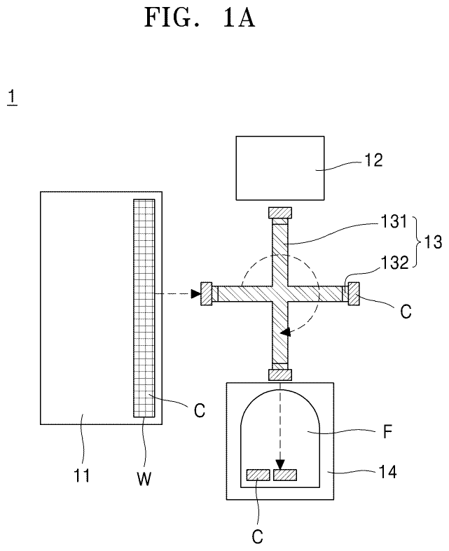

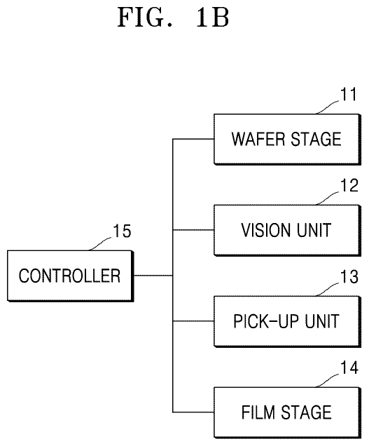

FIG. 1A is a perspective view illustrating an LED-chip sorting device 1 according to an embodiment.

FIG. 1B is a block diagram illustrating the LED-chip sorting device 1 according to an embodiment.

Referring to FIGS. 1A and 1B, according to an embodiment, the LED-chip sorting device 1 may include a wafer stage 11, a vision unit 12, a pick-up unit 13, a film stage 14, and a controller 15. However, the disclosure is not limited thereto, and as such, according to another embodiment, one or more of the wafer stage 11, the vision unit 12, the pick-up unit 13, the film stage 14, and the controller 15 may be omitted from the LED-chip sorting device 1, or one or more other components may be included in the LED-chip sorting device 1. According to an embodiment, one or more of the components (such as “units” or “modules”) of the sorting device 1 may be implemented by hardware, software or a combination of hardware and software. For example, the vision unit 12 and the pick-up unit 13 may include hardware or physical structures.

The wafer stage 11 may load a wafer W. For example, a wafer W may be loaded onto the wafer stage 11. One or more wafers W may be loaded on the wafer stage 11 from outside the wafer stage 11 using a loading unit. Here, the wafer W may include a plurality of LED chips C. In addition, the wafer stage 11 may further include a moving member capable of vertically and horizontally moving the wafer W or rotating the wafer W.

The LED chips C may be provided on the wafer W. According to an example, the LED chips C may be mounted on the wafer W in the form of flip chips. In this case, external connection terminals such as solder and bumps may be positioned between the wafer W and the LED chips C. In some embodiments, the LED chips C may be mounted on the wafer W in an epi-up form. In this case, the LED chips C may be electrically connected to the wafer W through bonding wires.

Referring to FIG. 1A, the LED chips C may be arranged on the wafer W in a matrix. Terminals may be formed on back surfaces of the LED chips for electrical connection to a circuit board. Although the wafer W is illustrated in FIG. 1A as having a rectangular shape for ease of illustration, the wafer W may have a circular shape.

According to an embodiment, the LED chips C to be sorted by the LED-chip sorting device 1 may be chip devices, which are cut through a sawing process after a semiconductor process and an electrode formation process are performed to impart an LED function to chip devices. The chip devices may be classified into grades according to LED characteristics. The LED chips C sorted by the LED-chip sorting device 1 may be shipped in a chip state or may be shipped after a subsequent process such as a packaging process or a module process.

The film stage 14 may load a film F. For example, a film F may be loaded the film stage 14. In this case, the film F may be an adhesive fluorescent film. For example, the film F may be a film in which a fluorescent material is mixed with a transparent resin such as a silicone resin. The film F may reduce color dispersion of light generated by the LED chips C. The film F may convert blue light generated by the LED chips C into white light. However, the disclosure is not limited thereto, and as such, the film F may be configured to convert light generated by the LED chips C in a different manner according to another embodiment. The film F may be loaded on the film stage 14 from outside the film stage 14 by using a loading unit. The film stage 14 may be provided independently of the wafer stage 11 at a distance from the wafer stage 11, but is not limited thereto.

The pick-up unit 13 may include a rotating member 131 and a pick-up head 132. The pick-up unit 13 may pick up the LED chips C from the wafer W. The pick-up unit 13 may pick up the LED chips C and arrange the LED chips C on the film F of the film stage 14. The pick-up unit 13 may rotate and move to pick up the LED chips C from the wafer W and arrange the LED chips C on the film F. The pick-up unit 13 may rotate clockwise or counterclockwise to arrange, on the film stage 14, the LED chips C picked up from the wafer stage 11.

The pick-up unit 13 may include a plurality of rotating members 131 and a plurality of pick-up heads 132. For example, the pick-up unit 13 may include four rotating members 131 each of which includes a pick-up head 132. However, the disclosure is not limited thereto, and as such, according to another embodiment, the number of rotating members 131 and pick-up heads 132 may be less than or greater than four. The pick-up heads 132 may be respectively coupled to ends of the rotating members 131, and the pick-up unit 13 may simultaneously move a plurality of LED chips C using the pick-up heads 132. The pick-up unit 13 may transfer the LED chips C from the wafer stage 11 to the film stage 14 according to the rotation direction of the rotating members 131. Referring to FIG. 1, because the pick-up unit 13 includes four rotating members 131 and four pick-up heads 132, the pick-up unit 13 may move four LED chips C at the same time. The LED chips C may be sequentially transferred from the wafer stage 11 to the film stage 14 by rotating the pick-up unit 13 clockwise.

The pick-up unit 13 may rotate and move adjacent to the wafer stage 11 to pick up LED chips C from the wafer W. In addition, the pick-up unit 13 may rotate and move adjacent to the film stage 14 to arrange, on the film F, the LED chips C picked up from the wafer W.

As shown in FIG. 1, the pick-up heads 132 may be provided on the ends of the rotating members 131. The pick-up heads 132 may pick up LED chips C from the wafer W using vacuum pressure. The pick-up unit 13 may further include separate vacuum pumps each capable of forming a vacuum, and connection parts provided on the ends of the rotating members 131 for picking up LED chips C.

The rotating members 131 may be plate-shaped members. According to another embodiment, a cross section of the rotating members 131 may have a circular shape or a polygonal shape such as a square shape, not being limited thereto. As shown in FIG. 1, the pick-up unit 13 may include four rotating members 131 arranged perpendicular to each other. The rotating members 131 may be arranged at right angles from each other in the direction of rotation of the pick-up unit 13. The pick-up heads 132 may be coupled to the ends of the rotating members 131, and a drive motor or the like may be coupled to a center portion of the pick-up unit 13 to drive the pick-up unit 13. The number of rotating members 131 is not limited to four. The pick-up unit 13 may include two or more rotating members 131 radially arranged in various combinations with respect to the center portion of the pick-up unit 13. For example, the pick-up unit 13 may include eight rotating members 131 spaced apart from each other at an angle of 45 degrees therebetween.

The pick-up unit 13 may selectively or collectively pick up LED chips C from the wafer W loaded on the wafer stage 11. According to an embodiment, the pick-up unit 13 is described as picking up LED chips C by a vacuum method. For example, the LED chips C may be attached to the pick-up unit based on a vacuum force applied to the LED chips C. However, the disclosure is not limited thereto, and as such, according to another embodiment, the pick-up unit 13 may pick up LED chips C by various other methods such as an adhesive method, an electrostatic method, or a hybrid method as needed. Therefore, the pick-up unit 13 may have various structures for picking up LED chips C.

The vision unit 12 may check whether an LED chip C picked up by the pick-up unit 13 is normal. According to an example embodiment, the vision unit 12 may be a camera or the vision unit 12 may include a camera or a sensor. According to an embodiment, the sensor may be an imaging sensor. The vision unit 12 may check, using a device such as the camera or the sensor, whether an LED chip C picked up by the pick-up unit 13 is normal. While the pick-up unit 13 picks up LED chips C from the wafer W of the wafer stage 11 and arranges the LED chips C on the film F of the film stage 14, the vision unit 12 may check whether the LED chips C are normal. That is, based on an operation of the vision unit 12, only normal LED chips C among LED chips C picked up by the pick-up unit 13 may be arranged on the film F of the film stage 14. According to an embodiment, the LED-chip sorting device 1 may sort LED chips C determined by the vision unit 12 as abnormal, separately from other LED chips C picked up by the pick-up unit 13. According to an embodiment, an LED chip C is identified as normal based on a determination that the LED chip C obtained by the vision unit 12 satisfies a predetermined criteria, and an LED chip C is identified as abnormal based on a determination that the LED chip C obtained by the vision unit 12 does not satisfy a predetermined criteria.

According to an embodiment, a camera of the vision unit 12 may capture an image of the LED chip C picked up by the pick-up unit 13 and compare the captured image with a stored image to determine if there is a match between the captured image and the stored image. If the vision unit 12 determines that the captured image matches the stored image, the vision unit 12 may identify the LED chip C as normal. However, if the vision unit 12 determines that the captured image does not match the stored image, the vision unit 12 may identify the LED chip C as abnormal. According to another embodiment, the camera of the vision unit 12 may capture the image of the LED chip C picked up by the pick-up unit 13, and a processor external to the vision unit 12 may compare the captured image with a stored image to determine whether there is a match between the captured image and the stored image. According to an embodiment, a captured image is identified as matching the stored image, if an amount of similarity between the captured image and the stored image is greater than or equal to a threshold value.

Although an example process of determining whether the LED chip C is normal and abnormal is described above, the disclosure is not limited thereto. As such, according to another embodiment, the vision unit 12 may determine whether the LED chip C is normal and abnormal based on another process.

The vision unit 12 may be independently or separately provided from the wafer stage 11 and the film stage 14. For example, the vision unit 12 may be provided at certain distances from the wafer stage 11 and the film stage 14. For example, the vision unit 12 may be provided at a first distance from the wafer stage 11 and the vision unit 12 may be provided at a first distance from the film stage 14. The first distance and the second distance may be equal to each other or different from each other. The vision unit 12 may be provided between the wafer stage 11 and the film stage 14 in the direction of rotation of the pick-up unit 13. For example, when the pick-up unit 13 rotates clockwise, the wafer stage 11, the vision unit 12, and the film stage 14 may be sequentially positioned clockwise. When the pick-up unit 13 rotates counterclockwise, the wafer stage 11, vision unit 12, and the film stage 14 may be sequentially positioned counterclockwise. According to an embodiment, the vision unit 12 may be provided between the wafer stage 11 and the film stage 14.

The controller 15 may control the pick-up unit 13 by selecting a direction (hereinafter referred to as a “pick-up direction” or “pick-up order”) in which the pick-up unit 13 picks up LED chips C from the wafer W. In an interacting relationship with the pick-up direction, the controller 15 may also control the pick-up unit 13 by selecting a direction (hereinafter referred to as “arrangement direction” or “arrangement order”) in which the pick-up unit 13 arranges picked-up LED chips C on the film F.

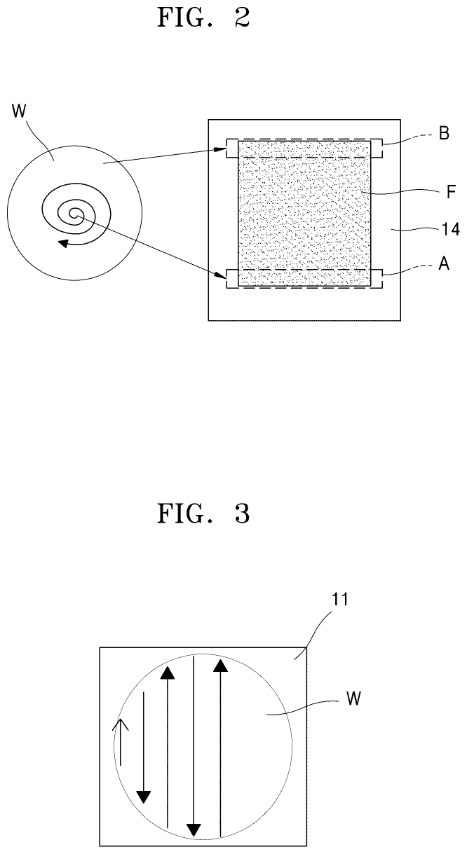

The controller 15 may select the pick-up direction from a first pick-up direction defined from a center portion of the wafer W toward an edge (or a periphery) of the wafer W, a second pick-up direction defined from the edge of the wafer W to the center portion of the wafer W, and a predetermined pick-up direction (refer to FIG. 2). In this case, the predetermined pick-up direction may be a pick-up direction that is different from the first pick-up direction and the second pick-up direction, for example, a pick-up direction in a comparative example (refer to FIG. 3).

According to an embodiment, the controller 15 may include one or more processors, such as, Central Processing Unit (also referred as “CPU”) or a state machine. According to an example embodiment, the controller may include, but is not limited to, an Application Specific Integrated Circuit (ASIC), an electronic circuit, a Field-Programmable Gate Arrays (FPGA), Programmable System-on-Chip (PSoC), a combinational logic circuit, and/or other suitable components that provide described functionality. According to an embodiment, the controller 15 may further include a memory for storing and executing a program code or instructions to implement one or more operations of the chip sorting device. For instance, the one or more processors may execute the instructions stored in the memory to control components of the chip sorting device. For example, the memory may be implemented as a volatile memory such as DRAM and SRAM, or a non-volatile memory such as Resistive RAM (ReRAM), Phase change RAM (PRAM) and NAND flash memory. The memory may also be implemented as a memory card (a multi-media card (MMC), an embedded MMC (eMMC), a secure digital (SD) card, or a micro SD card, etc.).

According to conditions of manufacturing processes of the wafer W, an edge portion of the wafer W may have lower chip power and a smaller thickness than the center portion of the wafer W. Due to conditions of manufacturing processes of the film F, an arrangement-start portion of the film F may be relatively thin and may thus have relatively low luminance. Therefore, when LED chips C picked up from the edge portion of the wafer W, which has relative low power are arranged on a relatively thin portion of the film F having a fluorescent material, the LED chips C may have poor luminance. To reduce LED chips C having poor luminance, LED chips C located in the center portion of the wafer W, which has high chip power may be arranged on the relatively thin portion of the film F. A method of controlling the pick-up unit 13 by selecting a pick-up direction will be described later.

FIG. 2 is a view illustrating a method of picking up and arranging LED chips using the LED-chip sorting device 1 according to an embodiment.

For ease of illustration, FIG. 2 only shows a wafer W and a film F loaded on the film stage 14. As such, the wafer stage 11, the pick-up unit 13, and the vision unit 12 are omitted from FIG. 2.

As described above, due to manufacturing process conditions of the wafer W, the chip power of the edge portion of the wafer W is lower than the chip power of the center portion of the wafer W. In addition, the thickness of LED chips C of the edge portion of the wafer W may be less than the thickness of LED chips C of the center portion of the wafer W. Due to manufacturing process conditions, a first end A of the film F may be thinner than a second end B of the film F.

According to an embodiment, the controller 15 of the LED-chip sorting device 1 may select a pick-up direction and an arrangement direction to reduce LED chips C having poor luminance. When the controller 15 selects a first pick-up direction defined from the center portion of the wafer W toward the edge of the wafer W, a first arrangement direction defined from the first end A of the film F toward the second end B of the film F may be determined as the arrangement direction. When the controller 15 selects a second pick-up direction defined from the edge of the wafer W toward the center portion of the wafer W, a second arrangement direction defined from the second end B of the film F toward the first end A of the film F may be determined as the arrangement direction.

The pick-up unit 13 may sequentially pick up LED chips C clockwise or counterclockwise in the first pick-up direction. The pick-up unit 13 may sequentially pick up LED chips C clockwise or counterclockwise in the second pick-up direction. According to an embodiment, FIG. 2 illustrates that the pick-up unit 13 may sequentially pick up LED chips C clockwise (depicted by the arrow) in the first pick-up direction from the center of the wafer to the edge of the wafer. According to an embodiment, because the pick-up unit 13 sequentially picks up LED chips C clockwise or counterclockwise, characteristics of the picked-up LED chips C may sequentially vary. For example, when the pick-up unit 13 picks up LED chips C clockwise or counterclockwise in the first pick-up direction, the thickness of the picked-up LED chips C may gradually decrease. In addition, when the pick-up unit 13 picks up LED chips C clockwise or counterclockwise in the second pick-up direction, the thickness of the picked-up LED chips C may gradually increase.

According to an embodiment, because the pick-up unit 13 sequentially picks up LED chips C clockwise or counterclockwise, long-wavelength LED chips C picked from the center portion of the wafer W may be arranged on a relatively thin portion of the film F, and short-wavelength LED chips C picked up from the edge portion of the wafer W may be arranged on a relatively thick portion of the film F. Therefore, errors occurring when low-power LED chips C are arranged on the relatively thin portion of the film F may be prevented. That is, LED chips C having poor luminance may be reduced by arranging high-power LED chips C first on the relatively thin portion of the film F.

According to an embodiment, the controller 15 may control the pick-up unit to sequentially pick up the plurality of LED chips from the wafer stage in a first order from a center portion of the wafer towards an edge portion of the wafer or a second order from the edge portion of the wafer towards the center portion of the wafer. In the first order or the second order, the controller 15 may be further configured to control the pick-up unit to pick up the plurality of LED chips a clockwise direction or a counterclockwise direction from the wafer.

FIG. 3 is a view illustrating pick-up directions of an LED-chip sorting device according to a comparative example.

Referring to FIG. 3, the LED-chip sorting device of the comparative example may pick up LED chips C from a wafer W in straight directions (depicted by the arrows) rather than a clockwise or counterclockwise direction. The LED-chip sorting device of the comparative example may pick up LED chips C from the wafer W in a zigzag direction. When LED chips C are picked up in the zigzag direction, high-power LED chips C of a center portion of the wafer W and low-power LED chips C of an edge portion of the wafer W may be picked up in turns.

A pick-up unit may sequentially arrange the picked-up LED chips C in a first arrangement direction (the A-to-B direction in FIG. 2) or in a second arrangement direction (the B-to-A direction in FIG. 2) sequentially in the order in which the LED chips C are picked up. Therefore, when LED chips C are picked up from the wafer W in the zigzag direction, low-power LED chip C picked up from the edge portion of the wafer W may be arranged on a relatively thin portion of the film F (refer to A in FIG. 2). When low-power LED chips C picked up from the edge portion of the wafer W are arranged on the relatively thin portion of the film F, the LED chips C may have poor luminance.

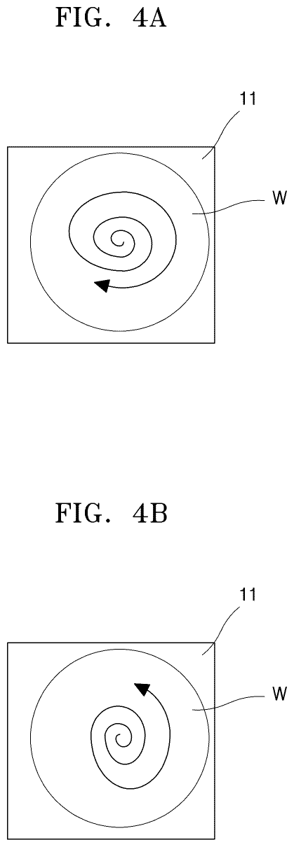

FIGS. 4A and 4B are views illustrating a pick-up direction of the LED-chip sorting device 1 according to an embodiment.

Referring to FIG. 4A, according to an embodiment, the pick-up unit 13 of the LED-chip sorting device 1 may pick up LED chips C from a wafer W clockwise in a first pick-up direction. According to an embodiment, because the pick-up unit 13 sequentially picks up LED chips C from the wafer W clockwise, long-wavelength LED chips C picked from a center portion of the wafer W may be arranged on a relatively thin portion of a film F, and short-wavelength LED chips C picked up from an edge portion of the wafer W may be arranged on a relatively thick portion of the film F. Therefore, errors occurring when low-power LED chips C are arranged on the relatively thin portion of the film F may be prevented. That is, LED chips C having poor luminance may be reduced by arranging high-power LED chips C first on the relatively thin portion of the film F.

FIG. 4B illustrates that the pick-up unit 13 may pick up LED chips C from the wafer W counterclockwise in the first pick-up direction. In both cases illustrates in FIGS. 4A and 4B, the pick-up unit 13 may arrange the LED chips C, picked up in the first pick-up direction, on the film F in a first arrangement direction (the A-to-B direction in FIG. 2).

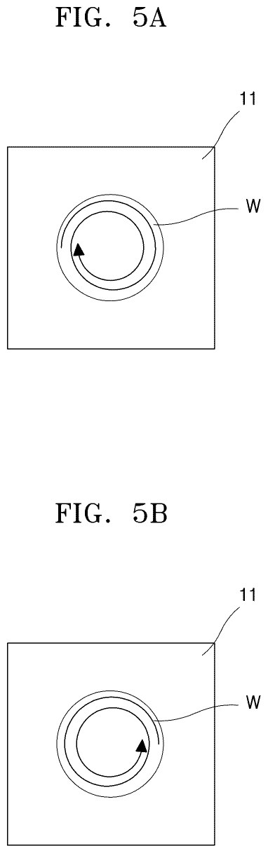

FIGS. 5A and 5B are views illustrating a pick-up direction of the LED-chip sorting device 1 according to an embodiment.

Referring to FIG. 5A, according to an embodiment, the pick-up unit 13 of the LED-chip sorting device 1 may pick up LED chips C from a wafer W clockwise in a second pick-up direction. According to an embodiment, because the pick-up unit 13 sequentially picks up LED chips C from the wafer W clockwise, long-wavelength LED chips C picked from a center portion of the wafer W may be arranged on a relatively thin portion of a film F, and short-wavelength LED chips C picked up from an edge portion of the wafer W may be arranged on a relatively thick portion of the film F. Therefore, errors occurring when low-power LED chips C are arranged on the relatively thin portion of the film F may be prevented. That is, LED chips C having poor luminance may be reduced by arranging high-power LED chips C first on the relatively thin portion of the film F.

FIG. 5B illustrates that the pick-up unit 13 may pick up LED chips C counterclockwise in the second pick-up direction. In both cases illustrated in FIGS. 5A and 5B, the pick-up unit 13 may arrange the LED chips C, picked up in the second pick-up direction, on the film F in a second arrangement direction (the B-to-A direction in FIG. 2).

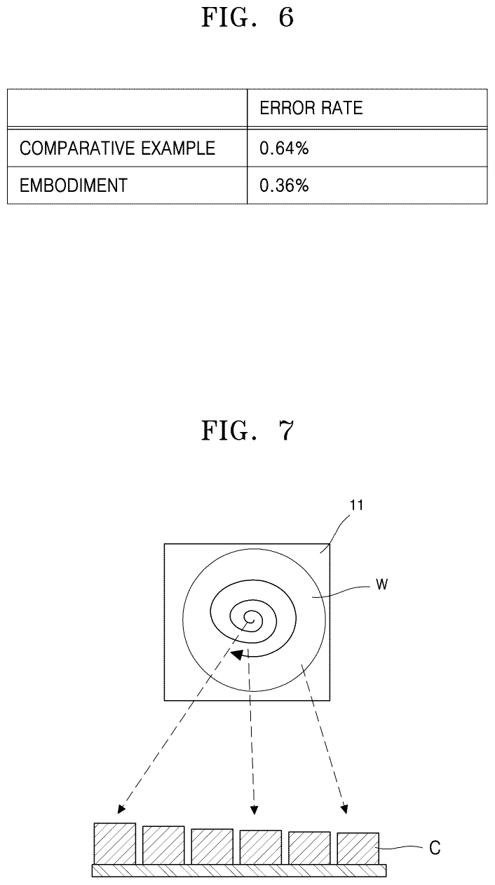

FIG. 6 is a table illustrating a comparison between effects by the LED-chip sorting device 1 and effects by the LED-chip sorting device of the comparative example.

Referring to FIG. 6, the LED-chip sorting device of the comparative example may pick up LED chips C from a wafer W as described with reference to FIG. 3. The LED-chip sorting device 1 of the embodiments may pick up LED chips C from a wafer W as described with reference to FIG. 4A, 4B, 5A or 5B.

When LED chips C are picked up from a wafer W (in a zigzag direction) as shown in FIG. 3, low-power LED chips C picked up from an edge portion of the wafer W may be arranged on a relatively thin portion (refer to “A” in FIG. 2) of a film F, and thus, the luminance error rate of LED chips C may be 0.64%. When LED chips C are picked up from a wafer W (in a first or second pick-up direction) as shown in FIG. 4A, 4B, 5A or 5B, high-power LED chips C picked up from a center portion of the wafer W may be arranged on a relatively thin portion of a film F, and the luminance error rate of LED chips C may be 0.36%. That is, the LED-chip sorting device 1 of the embodiments has an effect of reducing the luminance error rate of LED chips C by 0.28% compared with the LED-chip sorting device of the comparative example.

FIG. 7 is a view illustrating a method of arranging LED chips using the LED-chip sorting device 1 according to an embodiment.

Referring to FIG. 7, according to an embodiment, the LED-chip sorting device 1 may arrange LED chips C by selectively changing an arrangement method as needed. In processes requiring arrangement of LED chips C, the rate of defective products may be reduced by selectively changing the arrangement method of LED chips C.

For example, in a molding process, errors may be reduced by arranging LED chips C such that the thicknesses of the LED chips C may be uniformly arranged. When LED chips C are picked up in a zigzag direction as shown in FIG. 3, the thicknesses of picked-up LED chips C may not be uniformly arranged, and thus, the rate of error may increase in a molding process.

However, when LED chips C are picked up clockwise in a first pick-up direction as shown in FIG. 7, the thicknesses of the picked-up LED chips C may sequentially reduce. According to an embodiment, because LED chips C picked up from a center portion of a wafer F are relatively thick, adjacent LED chips C may have similar thicknesses when LED chips C are picked up clockwise in the first pick-up direction. When the LED chips C are picked up clockwise in the first pick-up direction, adjacent LED chips C are sequentially picked up, and thus, the thicknesses of picked-up LED chips C may be similar to each other. That is, when the LED-chip sorting device 1 of the embodiments is used in a molding process, the thicknesses of adjacently arranged LED chips C may be similar to each other, and thus, the rate of error in the molding process may be reduced. Although FIG. 7 illustrates an example in which LED chips C are picked up clockwise in the first pick-up direction, embodiments are not limited thereto. For example, LED chips C may be picked up counterclockwise in the first pick-up direction. In addition, LED chips C may be picked up clockwise or counterclockwise in a second pick-up direction.

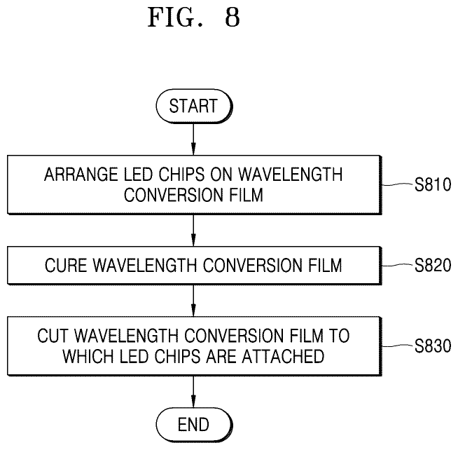

FIG. 8 is a flowchart illustrating an LED chip manufacturing method according to an embodiment.

Referring to FIG. 8, the LED chip manufacturing method of the embodiments may include an operation S810 of arranging LED chips C on a film F. According to an embodiment, the film F may be a wavelength conversion film.

The arranging of LED chips C on the wavelength conversion film F may include picking up LED chips C from a wafer W including LED chips C and loaded on the wafer stage 11 by using the pick-up unit 13. In addition, the arranging of LED chips C on the wavelength conversion film F may also include arranging the LED chips C on the wavelength conversion film F provided on the film stage 14 by using the pick-up unit 13. The arranging of LED chips C on the wavelength conversion film F will be further described later.

In operation S820, the LED chip manufacturing method may include curing the wavelength conversion film F. For example, after attaching the LED chips C to the wavelength conversion film F, the wavelength conversion film F may be cured.

In operation S830, the LED chip manufacturing method may include cutting the wavelength conversion film F to which the LED chips C are attached. A plurality of LED chips may be manufactured by cutting, with a blade or the like, the wavelength conversion film F to which the LED chips C are attached. That is, the LED chips C including the wavelength conversion film F may be individualized.

In addition, an LED package may be manufactured using the LED chips C including the wavelength conversion film F.

A plurality of individually-cut LED chips C may be arranged on a package substrate at predetermined intervals. First and second bonding pads may be formed on the package substrate. The LED chips C may be mounted on the first and second bonding pads, and first and second electrodes of the LED chips C may be electrically connected to the first and second bonding pads using conductive adhesive layers such as solder bumps.

The package substrate may be a substrate for forming a package in a wafer state, that is, for manufacturing a wafer level package (WLP), and may be flat on both sides such that a package on which the LED chips C are mounted may have a small size on the level of the size of the LED chips C.

The package substrate may be a plate-shaped substrate, for example, a substrate including a material such as Si, sapphire, ZnO, GaAs, SiC, MgAl₂O₄, MgO, LiAlO₂, LiGaO₂, or GaN. In an embodiment, a Si substrate may be used as the package substrate. However, the material of the package substrate is not limited thereto. For example, the package substrate may include an organic resin material containing epoxy, triazine, silicone, polyimide, or the like, or another organic resin material by considering heat dissipation characteristics and electrical connection of the LED package. In another example, the package substrate may include a ceramic material such as Al₂O₃ or AlN having characteristics such as high heat resistance, high thermal conductivity, and high reflective efficiency to improve heat dissipation characteristics and light-emitting efficiency. In addition to the substrates described above, a printed circuit board or a lead frame may also be used as the package substrate.

The LED package may be cut with a blade or the like into a plurality of LED packages. That is, the LED package may be divided into a plurality of LED packages including the LED chips C to which the wavelength conversion film F is attached.

In addition, a white light source module may be manufactured by combining, as a module, the plurality of LED packages including the LED chips C to which the wavelength conversion film F is attached. That is, a white light source module may be manufactured by modularizing the LED package. In addition, a white light source module may be manufactured by mounting, on a module substrate, the LED chips C to which the wavelength conversion film F is attached.

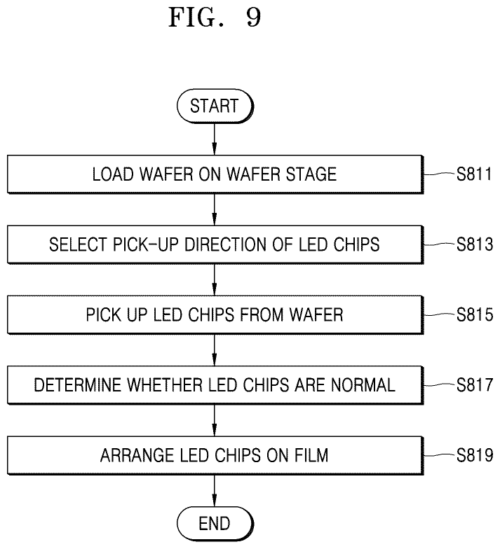

FIG. 9 is a flowchart specifically illustrating the operation of arranging LED chips on a wavelength conversion film in the LED chip manufacturing method, according to an embodiment.

Referring to FIG. 9, according to an embodiment, in operation S811, the method of controlling the LED-chip sorting device 1 may include loading a wafer W including LED chips C on a wafer stage 11. One or more wafers W may be loaded on the wafer stage 11 from outside the wafer stage 11 by using a loading unit. According to an embodiment, the wafer W may include a plurality of LED chips C. The LED chips C may be arranged on the wafer W in a matrix.

In operation S813, the method of controlling the LED-chip sorting device 1 may include selecting a pick-up direction of the LED chips C. The controller 15 may select the pick-up direction of the LED chips C. According to an embodiment, the controller 15 may select one of a first pick-up direction (refer to FIG. 4A or 4B) defined from a center portion of the wafer W toward the edge of the wafer W, a second pick-up direction (refer to FIG. 5) defined from the edge of the wafer W to the center portion of the wafer W, and a zigzag pick-up direction described in the comparative example shown in FIG. 3. According to an embodiment, the controller 15 may control the pick-up unit 13 to select the pick-up direction of the LED chips C based on a user's input. However, the disclosure is not limited thereto, and as such, according to another embodiment, the controller 15 may control the pick-up unit 13 to select the pick-up direction of the LED chips C based on another input or determination by the controller. According to an embodiment, the pick-up direction or order of the LED chips C may be selected based on a characteristic of the wafer W and/or a characteristic of the film F. For example, the pick-up direction or order of the LED chips C may be selected to match the thickness of LED chips C with the thickness of the film F. According to an embodiment, a first LED chip C having a first thickness may be placed in a first portion of the film F having a second thickness, and a second LED chip C having a third thickness may be placed in a second portion of the film F having a fourth thickness. Here, the first thickness may be greater than the third thickness, and the second thickness may be smaller than the fourth thickness. As such, the first portion of the film F, which may be thinner than the second portion of the film F, may be provided with a first LED chip C, which is thicker than the second LED chip C.

In operation S815, the method of controlling the LED-chip sorting device 1 may include picking up the LED chips C from the wafer W. The pick-up unit 13 may pick up the LED chips C in the pick-up direction selected by the controller 15. When the controller 15 selects the first pick-up direction, the pick-up unit 13 may pick up the LED chips C from the wafer W clockwise or counterclockwise in the first pick-up direction. When the controller 15 selects the second pick-up direction, the pick-up unit 13 may pick up the LED chips C from the wafer W clockwise or counterclockwise in the second pick-up direction. When the zigzag pick-up direction is selected as needed by a user instead of the first pick-up direction and the second pick-up direction, the pick-up unit 13 may pick up the LED chips C from the wafer W in the zigzag pick-up direction.

In operation S817, the method of controlling the LED-chip sorting device 1 may include determining whether the LED chips C are normal. The vision unit 12 may check whether the LED chips C picked up by the pick-up unit 13 are normal. The vision unit 12 may check, using a device such as a camera, whether the LED chips C picked up by the pick-up unit 13 are normal. While the pick-up unit 13 picks up the LED chips C from the wafer W placed on the wafer stage 11 and arranges the LED chips C on a film F placed on the film stage 14, the vision unit 12 may check whether the LED chips C are normal. That is, owing to the use of the vision unit 12, only normal LED chips C among the LED chips C picked up by the pick-up unit 13 may be arranged on the film F of the film stage 14. According to an embodiment, the LED-chip sorting device 1 may separately sort LED chips C determined by the vision unit 12 as being abnormal among the LED chips C picked up by the pick-up unit 13.

In operation S819, the method of controlling the LED-chip sorting device 1 may include arranging the LED chips C on the film F. The pick-up unit 13 may arrange the LED chips C picked up from the wafer W on the film F of the film stage 14. The controller 15 may arrange the LED chips C in an interacting relationship with the pick-up direction.

The pick-up unit 13 may sequentially arrange picked-up LED chips C in a first arrangement direction (the A-to-B direction in FIG. 2) or a second arrangement direction (the B-to-A direction in FIG. 2) sequentially in the order in which the LED chips C are picked up. For example, when the controller 15 selects the first pick-up direction defined from the center portion of the wafer W toward the edge of the wafer W, the first arrangement direction defined from an end A of the film F toward another end B of the film F may be determined as the arrangement direction. When the controller 15 selects the second pick-up direction defined from the edge of the wafer W toward the center portion of the wafer W, the second arrangement direction defined from the other end B of the film F toward the end A of the film F may be determined as the arrangement direction.

While the inventive concept has been particularly shown and described with reference to embodiments thereof, it will be understood that various changes in form and details may be made therein without departing from the spirit and scope of the following claims.

What is claimed is:

1. A chip sorting device comprising:
a wafer stage configured to load a wafer comprising a plurality of light emitting diode (LED) chips on the wafer stage;
a film stage configured to load a film on the film stage;
a pick-up unit configured to place, on the film loaded on the film stage, one or more of the plurality of LED chips loaded on the wafer stage; and
a controller configured to control the pick-up unit to sequentially pick up the plurality of LED chips from the wafer stage in a first direction from a center portion of the wafer towards an edge portion of the wafer or a second direction from the edge portion of the wafer towards the center portion of the wafer.

2. The chip sorting device of claim 1, wherein the pick-up unit is further configured to pick up the plurality of LED chips based on a vacuum force applied to the plurality of LED chips.

3. The chip sorting device of claim 1, wherein the controller is further configured to change a current pick-up direction to one of the first direction, the second direction, and a third direction.

4. The chip sorting device of claim 1, wherein in the first direction or the second direction, the controller is further configured to control the pick-up unit to pick up the plurality of LED chips a clockwise direction or a counterclockwise direction from the wafer.

5. The chip sorting device of claim 1, further comprising a vision unit configured to check whether each of the plurality of LED chips satisfies a criteria.

6. The chip sorting device of claim 5, wherein the pick-up unit is further configured to rotate in a direction along the wafer stage, the vision unit, and the film stage.

7. The chip sorting device of claim 1, wherein the pick-up unit comprises:
a plurality of pick-up heads configured to pick up the plurality of LED chips loaded on the wafer stage; and
a plurality of rotating members configured to rotate the plurality of pick-up heads.

8. The chip sorting device of claim 7, wherein the plurality of rotating members are radially arranged, and
wherein each of the plurality of pick-up heads is provided at an end of each of the plurality of rotating members.

9. The chip sorting device of claim 1, wherein the pick-up unit is further configured to sequentially arrange the plurality of LED chips on the film in a direction from a first end of the film to a second end of the film.

10. A chip sorting device comprising:
a wafer stage configured to load a wafer comprising a plurality of light emitting diode (LED) chips on the wafer stage;
a film stage configured to load a film on the film stage;
a pick-up unit configured to place, on the film loaded on the film stage, one or more of the plurality of LED chips loaded on the wafer stage; and
a controller configured to select a pick-up direction in which the plurality of LED chips are picked up from the wafer stage and an arrangement direction in which the plurality of LED chips are placed on the film based on an interacting relationship between the pick-up direction and the arrangement direction.

11. The chip sorting device of claim 10, wherein the controller is further configured to:
select, as the pick-up direction, a first direction from a center portion of the wafer towards an edge portion of the wafer, and
select, as the arrangement direction, a first arrangement direction from a first end of the film having a first thickness to a second end of the film having a second thickness greater than the first thickness.

12. The chip sorting device of claim 11, wherein the controller is further configured to:
select, as the pick-up direction, a second-up direction from the edge portion of the wafer towards the center portion of the wafer, and
select, as the arrangement direction, a second arrangement direction from the second end of the film to the first end of the film.

13. The chip sorting device of claim 10, wherein the controller is further configured to control the pick-up unit to pick up the plurality of LED chips a clockwise direction or a counterclockwise direction from the wafer.

14. The chip sorting device of claim 10, further comprising a vision unit configured to check whether each of the plurality of LED chips satisfies a criteria.

15. The chip sorting device of claim 14, wherein the pick-up unit is further configured to rotate in a direction along the wafer stage, the vision unit, and the film stage.

16. A method of manufacturing a light-emitting diode (LED) chip, the method comprising:
arranging a plurality of LED chips on a wavelength conversion film;
curing the wavelength conversion film; and
cutting the wavelength conversion film on which the plurality of LED chips are arranged,
wherein the arranging of the plurality of LED chips on the wavelength conversion film comprises:
picking up, by a pick-up unit, the plurality of LED chips from a wafer comprising the plurality of LED chips and loaded on a wafer stage; and
arranging, by the pick-up unit, the plurality of LED chips on the wavelength conversion film provided on a film stage, and
wherein the picking up of the plurality of LED chips comprises selecting a pick-up direction in which the plurality of LED chips are picked up.

17. The method of claim 16, wherein the selecting of the pick-up direction comprises selecting, as the pick-up direction, one of:
a first direction for picking up the plurality of LED chips from a center portion of the wafer towards an edge portion of the wafer;
a second direction for picking up the plurality of LED chips from the edge portion of the wafer towards the center portion of the wafer; and
a third pick-up direction different from the first direction and the second direction.

18. The method of claim 16, wherein the picking up of the plurality of LED chips comprises picking up the plurality of LED chips in a clockwise direction or a counterclockwise direction from the wafer.

19. The method of claim 16, wherein the arranging of the plurality of LED chips on the wavelength conversion film provided on the film stage comprises arranging the LED chips based on a relationship with the pick-up direction.

20. The method of claim 16, wherein the arranging of the plurality of LED chips on the wavelength conversion film further comprises determining whether the plurality of LED chips picked up by the pick-up unit satisfies a criteria.
